(19) United States
(12) Patent Application Publication
(10) Pub. No.: US 2007/0259463 A1
(43) Pub. Date: Nov. 8, 2007

(54) Wafer-level method for thinning imaging sensors for backside illumination

(76) Inventor: Youssef Abedini, Fremont, CA (US)

Correspondence Address: Calvin B . Ward;Suite 305, 18 Crow Canyon Court, San Ramon, CA, 94583, US

(21) Appl. No.: 11/416,669

(22) Filed: May 2, 2006

(51) Int. Cl. H01L 21/00

(52) U.S. Cl. 438/22

(57) ABSTRACT

A method for fabricating an imaging system is disclosed. The method starts with a wafer having front and backsides. A plurality of the imaging systems are fabricated on the front side of the wafer, each imaging system includes an imaging array that includes a plurality of pixels. Each pixel converts light incident on that pixel to an electrical signal. Support circuitry surrounds each imaging array. A mask is generated on the backside of the wafer in areas opposite to the support circuitry. The backside of the wafer is then etched in areas not covered by the mask to remove material opposite the imaging array thereby creating ridges surrounding each of the imaging arrays. The ridges have a thickness greater than the thickness of the wafer at locations having the imaging arrays. The method can be used to fabricate backside imagers constructed from either CCD or CMOS imaging arrays

### BACKGROUND OF THE INVENTION

Semiconductor image sensing arrays typically consist of an array of pixel elements that are fabricated on the front side of a semiconductor wafer. Each pixel includes an area of semiconductor in which photons are converted to hole-electron pairs. The electrons or holes are collected for each pixel, and the collected charge is then measured to provide a measure of the amount of light that was incident on that pixel. The area in which the photons are converted is covered by a number of layers that depend on the particular type of sensing array. For example, in CCD sensors, the photon conversion area is covered by polysilicon gates that define the boundaries of each pixel and which are used to shift charge along columns of pixels. In addition, there are typically additional layers of glass that isolate the various metal layers that form other connections in the sensor. In a front side illuminated sensor, the incident photons must pass through these layers and the electrodes to reach the photon conversion area. Since these structures absorb a significant number of photons, the performance of front side illuminated sensors is less than ideal.

Hence, sensors in which the photons to be measured enter the sensor from the backside of the die have been developed. In such sensors, the backside of the wafer is thinned to a thickness that depends on the wavelength of the light to be measured. Since the backside of the wafer is free of additional structures, the problems discussed above are avoided.

Unfortunately, the final thickness of the wafer is usually so small that the thinned wafer cannot be handled after the thinning process unless the wafer is attached to some other substrate for support. For many applications, the final wafer thickness is less than 100 μm. If the front side processing is complete when the wafer is thinned, the wafer can be bonded to a carrier such as a glass plate prior to the thinning process. After the thinning process, the vias are opened in the glass plate and filled with metal to provide connections to the circuitry on the front side of the wafer. Unfortunately, the thickness of the carrier must be hundreds of microns, and there is a limit to the aspect ratio of the vias that opened. Hence, to penetrate the required thickness of glass, the vias must have a relatively large diameter. This aspect ratio limitation, in turn, places limits on the number of such connections and the spacings of the connections.

The number of connections required depends on the particular sensor design. In hybrid sensors, a CCD chip is often bonded to a CMOS chip. The CCD chip contains pixels organized into columns. The charge in each pixel is shifted down the column and off of the CCD chip to the CMOS chip, which includes the sense amplifiers and other drive circuitry used by the CCD chip. This arrangement takes advantage of the strengths of both fabrication systems. For example, in low light applications, the amount of charge generated by each pixel is quite small; hence, a high degree of amplification is needed. If the charge to voltage conversion is performed on the CCD substrate, the amplifier is limited to the devices that can be constructed using the CCD fabrication process. CCDs require high charge-transfer efficiency. To achieve this efficiency, CCDs are fabricated using specialized processes that minimize imperfections in the semiconductor material. Most logic circuitry relies on CMOS fabrication techniques. In general, the starting material and fabrication processes used to produce CCD and CMOS devices are incompatible. For example, conventional CMOS fabrication processes require one layer of doped polysilicon gate electrodes and 4 or more layers of interconnect metals whereas CCD device structures require 2 or 3 layers of poly & only one or two layers of metal. These incompatibilities typically reduce the efficiency of CCD devices to unacceptable levels. Hence, it has been found advantageous to provide the amplification devices and other logic or signal processing on separate, dedicated CMOS chips that are attached to the CCD chip.

The chips are bonded together using bumps and/or studs of indium and/or other suitable metallic vertical interconnect material. The spacing of the bumps depends on the spacing of the columns in the CCD chip. In many CCD sensor designs, the required spacing is too small to allow the type of permanent front side support discussed above. In addition, the large vias increase the capacitance of the connection between the last pixel in a column and the readout amplifier. This high capacitance causes problems in designs requiring high amplification factors, and very low noise.

In principle, the backside of the CCD imaging chip can be thinned and processed after the CCD chip has been bonded to the CMOS chips. However, this approach requires that each CCD chip or hybrid sensor assembly be thinned separately which substantially increases yield loss and the cost of the final imager. If thinning is performed at the wafer level before bump/stud processing, handling of thin CCD wafer is problematic. If a handle “carrier” wafer is attached to the backside to support the thinned wafer, the complexity and cost increase. If the thinning is performed at the wafer level after bonding a CCD wafer to a CMOS wafer, the yield is reduced because of defects in the CMOS or CCD wafers. In addition, full wafer to full wafer bonding, “wafer scale bonding”, at a commercial scale is not yet available at an acceptable price.

### SUMMARY OF THE INVENTION

The present invention includes a method for fabricating an imaging system. The method starts with a wafer having front and back sides. A plurality of the imaging systems are fabricated on the front side of the wafer, each imaging system includes an imaging array that includes a plurality of pixels. Each pixel converts light incident on that pixel to an electrical signal. Support circuitry surrounds each imaging array. A mask is generated on the backside of the wafer in areas opposite to the support circuitry. The backside of the wafer is then etched in areas not covered by the mask to remove material opposite the imaging array, thereby creating ridges surrounding each of the imaging arrays. The ridges have a thickness greater than the thickness of the wafer at locations having the imaging arrays. The wafer is etched to a thickness between approximately 10 μm and 200 μm in regions having the imaging arrays. The method can be used to fabricate backside imagers constructed from either CCD or CMOS imaging arrays

### BRIEF DESCRIPTION OF THE DRAWINGS

FIG. 1 is a top view of wafer 100 comprising four CCD chips.

FIG. 2 is a cross-sectional view of wafer 100 through line 2-2 shown in FIG. 1.

FIGS. 3-7 are cross-sectional views of a portion of a wafer 40 having two backside illuminated dies at various stages in the wafer thinning process.

### DETAILED DESCRIPTION OF THE PREFERRED EMBODIMENTS OF THE INVENTION

The present invention is based on the observation that each imaging chip includes a peripheral region that is used for scribe lanes and circuitry other than the circuitry involved in the pixel-by-pixel charge conversion. When the wafer is thinned, these regions are left unthinned and provide a ribbed structure that provides sufficient strength to allow the thinned wafer to be handled and finally diced. Hence, all the imager chips can be thinned at the wafer level simultaneously, which provides a significant cost advantage.

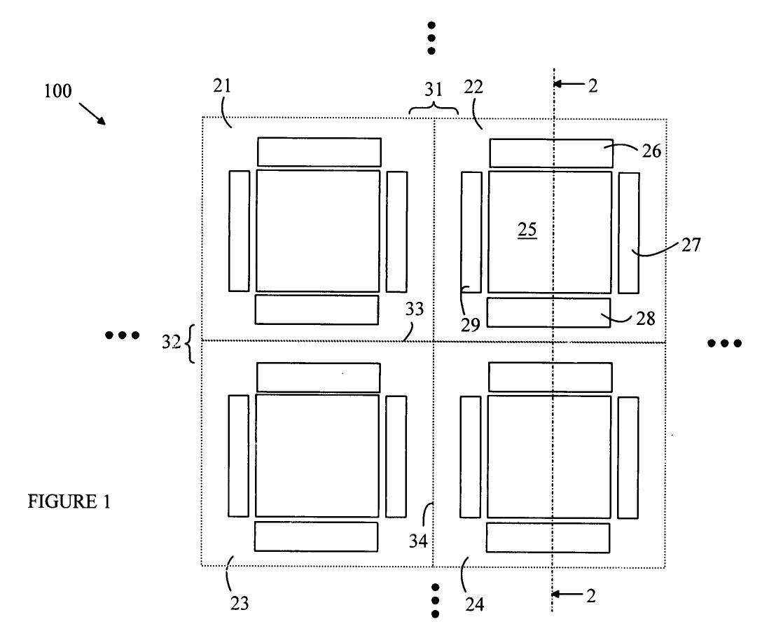

Refer now to FIG. 1, which illustrates a portion of a wafer 100 containing CCD chips of a typical construction after the circuitry on the front side of the wafer has been fabricated. FIG. 1 is a top view of wafer 100. Four CCD chips are shown in FIG. 1 at 21-24. Each chip includes an optical sensing area 25 and support circuitry 26-29 that is constructed in the regions around optical sensing area 25. Optical sensing area 25 is typically a two-dimensional array of pixel elements in which each pixel element accumulates charge when exposed to light. The pixel elements are typically organized into columns that run parallel to line 2-2 and rows that run perpendicular to the columns. In a CCD, each column can be operated as a shift register such that the charges accumulated at each pixel element can be shifted out of one of the ends of the column containing that pixel element. The shifted charges are then measured by circuitry that can either be on the chip itself, on a separate chip that is connected to the CCD chip, or circuitry that is partially on the CCD chip and partially on the separate chip. If the processing circuitry requires a separate chip, the two chips are connected by pads. Regions 26 and 28 at the end of the columns include this readout and connection circuitry. In embodiments in which a number of columns share a sense amplifier, the area at the ends of the columns also includes multiplexers that are structurally similar to the column shift registers. In addition, the rows include electrodes that run parallel to each row and connect to the gates in the various pixel elements. These row electrodes terminate on circuitry and/or pads used to connect the row electrodes to off-chip driving circuitry. These elements are typically located in regions 27 and 28.

A significant area between the chips is reserved for scribe lanes. Exemplary scribe lanes are shown at 31 and 32. After the wafer level fabrication is completed, the chips are separated by making cuts along lines 33 and 34. The scribe lanes provide sufficient area to assure that any variation in the cuts does not result in damage to the circuitry on the chip.

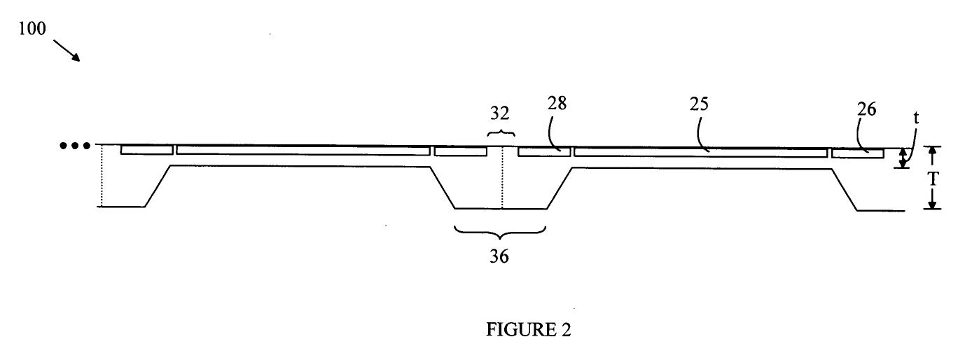

Refer now to FIG. 2, which is a cross-sectional view of wafer 100 through line 2-2 shown in FIG. 1 after the areas under the optical sensing areas have been thinned. The areas under the optical sensing area are thinned to a thickness t while the areas under the support circuitry and scribe lanes are significantly thicker, i.e., T. The precise thickness to which the areas under the optical sensing area are thinned depends on the particular chip design, operating conditions and/or performance requirements. This thickness can typically vary from 10 μm to 200 μm. T is 250 μm or greater. These thicker areas form a network of ribs 36 that stiffen the thinned wafer sufficiently to allow the wafer to be handled without damaging the chips during subsequent processing and separation without requiring the bonding of a support structure to the front side of the wafer.

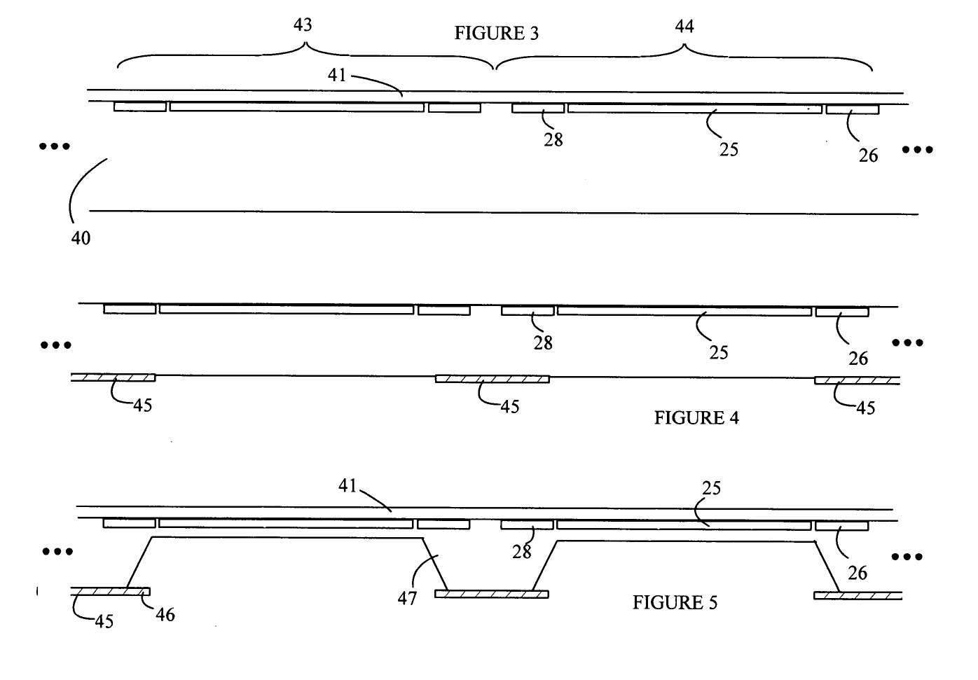

Refer now to FIGS. 3-7, which are cross-sectional views of a portion of a wafer 40 having two backside illuminated dies 43 and 44 at various stages in the wafer thinning process. After the front side device fabrication of the wafers is completed, a protective layer 41 is placed over the front side of the wafer to protect the components on the front side from mechanical or chemical damage during the subsequent processing steps as described below. The protective layer can include supportive tapes or substrates as well as protective layers such as hardened polymers and/or inorganic or metallic chemically resistant films.

Referring to FIG. 4, the backside of the wafer is mechanically thinned and polished to a thickness that is sufficient to provide structural support for the wafer. The thinning can be accomplished with a combination of mechanical lapping or grinding and/chemo-mechanical polishing. The thinned surface is cleaned with solvents or organic strippers/oxidizers or dry ashing/cleaning tools after the thinning and polishing operation. The resultant wafer is typically 350 μm to 450 μm. The front side protective layer 41 can be partially removed after the thinning process, or left as protection against further backside processing damage.

A hard mask is then deposited on the thinned surface as shown at 45. The mask is typically a layer of metal or composite layers of metallic films having openings that define the areas under optical sensing areas 25 that are to be thinned further. The mask deposition and patterning is conventional in the art, and hence, will not be discussed in detail here. For the purposes of the present discussion, a patterned hard mask can be formed by a lithographic process, deposition and lift-off of the metallic film in the regions under optical sensing areas 25. The mask is preferably constructed from layers of platinum, or other metals, or materials such as silicon nitride that are resistant to silicon etchants used in subsequent selective thinning operations, as described below.

Referring to FIG. 5, the wafer is then thinned in regions defined by mask 25 to a thickness that is determined by the particular imaging array design specifications. In general, the final thickness will determine the range of wavelengths that can be viewed by the final imaging die. Hence, the thickness will depend on the design specification of the final device. A thickness in the range of 10 μm to 200 μm can be provided, the smaller thickness corresponding to imaging light in the blue region of the spectrum, and the larger thickness corresponding to that of the near infra red region of the spectrum.

The wafer can be thinned by any suitable method. For example, a combination of chemical and dry etching can be utilized. The final thickness can be set by a timed etch or, in some cases, by an etch stop. For example, in CCD imagers in which the light conversion is performed in epitaxially grown silicon on the surface of the wafer, the underlying silicon is preferably etched back to the silicon-epitaxial silicon boundary. Etch procedures that stop on such a boundary are known to the art. For instance, a solution of properly proportioned HF, nitric and acetic acids, and potassium permanganate etch the heavier doped regions preferentially but does not significantly attack the lightly doped epitaxial layer.

Refer again to FIG. 5. After the etching operation, the thinned areas under the optical sensing areas will be separated by ridges 47 that provide structural support for the thinned areas. The width of the ridges will depend on the particular imaging design. In a typical CCD imaging chip, the support circuitry can require over 1000 μm of die area in addition to a typical 100 μm scribe lane. Hence, the width of the ridges can exceed 2100 μm. If the width needs to be increased for a particular design, the area normally occupied by the support circuitry in the chip periphery region or the scribe lane, width can be increased accordingly to provide the required space.

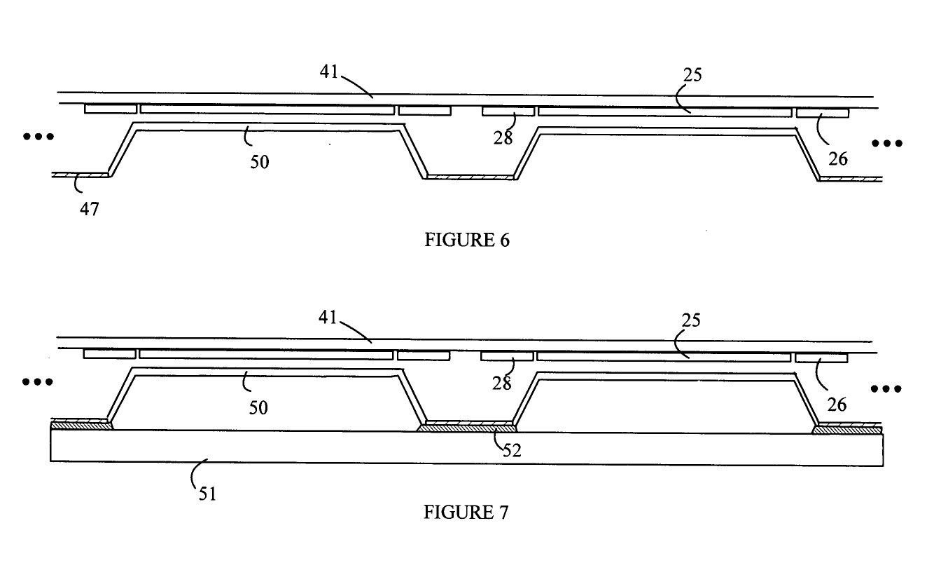

Mask 45 will typically have overhanging sections 46 because of the undercutting of the mask during the etching process. These overhangs and all or a portion of the thickness of the hard mask layer can be removed by a suitable etchant. If the hard mask is metallic, since the ratio of the surface area to the thickness of the metal layer is twice as large in the overhang region, the overhangs can be removed while leaving a portion of the metal layer intact to act as a backside electrode or thermal contact, as shown at 47 in FIG. 6. If, for instance, the metal is platinum, an aqua regia mixture (HCl/Nitric acid combination) can be utilized which can also remove the metallic (silicon etch stop) from the front side of the silicon wafer, if applicable.

After the hard mask layer has been stripped (or etched back), additional backside processing can be performed. For example, antireflective coatings 50 can be deposited on the backside in the thinned areas.

In some cases, it is advantageous to provide backside protection to further support the wafer or dies during additional fabrication steps. For example, a handle wafer 51 can be bonded to the ribs by a suitable adhesive 52 to protect the backside and provide additional strength. The handle wafer can be cut at the time the individual CCD wafers are singulated. In this case, the handle wafer can provide additional strength to the individual dies during subsequent processing such as bump formation and to individual dies during sawing and bonding the imaging array dies to one or more CMOS dies having amplifiers and/or other processing circuitry thereon.

The above-described embodiments have utilized CCD detector arrays. However, the method of the present invention can be used with CMOS imaging arrays that are illuminated from the backside, and hence, require backside thinning for proper performance.

Various modifications to the present invention will become apparent to those skilled in the art from the foregoing description and accompanying drawings. Accordingly, the present invention is to be limited solely by the scope of the following claims.

What is claimed is:

1. A method for fabricating an imaging system, said method comprising:
providing a wafer having a front side and a backside;
fabricating a plurality of said imaging systems on said front side of said wafer, each imaging system comprising an imaging array comprising a plurality of pixels, each pixel converting light incident on that pixel to an electrical signal and support circuitry surrounding that imaging array;
generating a mask on said backside of said wafer in areas opposite to said support circuitry; and
etching said backside of said wafer in areas not covered by said mask to remove wafer substrate material opposite said imaging array thereby creating ridges surrounding each of said imaging arrays, said ridges having a thickness greater than the thickness of said wafer at locations having said imaging arrays.

2. The method of claim 1 wherein said wafer is etched to a thickness between approximately 10 μm and 200 μm in regions having said imaging arrays.

3. The method of claim 1 wherein said mask comprises an inorganic material.

4. The method of claim 1 wherein said mask comprises a layer of a metal.

5. The method of claim 1 further comprising removing a portion of said mask after said backside is etched.

6. The method of claim 1 further comprising applying a coating to said backside of said wafer after said wafer has been etched.

7. The method of claim 1 further comprising uniformly thinning said wafer from said backside prior to generating said mask.

8. The method of claim 7 wherein said wafer is between 200 μm and 400 μm after being uniformly thinned.

9. The method of claim 7 further comprising covering said front side of said wafer with a protective layer prior to uniformly thinning said wafer.

10. The method of claim 1 wherein said imaging array comprises a CCD imaging array.

11. The method of claim 1 wherein said imaging array comprises a CMOS imaging array.
